(19) United States
(12) Patent Application Publication
(10) Pub. No.: US 2025/0372349 A1
(43) Pub. Date: Dec. 4, 2025

(54) PLASMA PROCESSING APPARATUS, POWER SUPPLY SYSTEM, AND ETCHING METHOD

(71) Applicant: Tokyo Electron Limited, Tokyo (JP)

(72) Inventors: Daisuke NISHIDE, Miyagi (JP); Masanori HOSOYA, Miyagi (JP)

(73) Assignee: Tokyo Electron Limited, Tokyo (JP)

(21) Appl. No.: 19/299,608

(22) Filed: Aug. 14, 2025

Related U.S. Application Data
(63) Continuation of application No. PCT/JP2024/000811, filed on Jan. 15, 2024.

(30) Foreign Application Priority Data
Feb. 21, 2023 (JP) 2023-025347

(51) Int. Cl. H01J 37/32; H01L 21/311

(52) U.S. Cl. CPC H01J 37/32174; H01J 37/3244; H01J 2237/332; H01J 2237/334; H01L 21/31116; H01L 21/31144

(57) ABSTRACT

A plasma processing apparatus includes a source RF generator and a bias RF generator. The source RF signal has a first source power level in a first deposition priority period and a second deposition priority period, and has a second source power level smaller than the first source power level in a first etching priority period and a second etching priority period. The first deposition priority period is shorter than the second deposition priority period. The first etching priority period is longer than the second etching priority period. The bias RF signal has a first bias power level in the first deposition priority period and the second deposition priority period, and has a second bias power level larger than the first bias power level in the first etching priority period and the second etching priority period.

### CROSS-REFERENCE TO RELATED APPLICATIONS

The present application is a bypass continuation of international PCT Application No. PCT/JP2024/000811 filed on Jan. 15, 2024, which claims priority under 35 U.S.C. § 119 to Japanese Patent Application No. 2023-025347 filed on Feb. 21, 2023, the entire contents of each are incorporated herein by reference. The present application is related to Japanese Patent Application No. 2022-93071 and Japanese Patent Application No. 2022-93119 filed on Jun. 8, 2022, the entire contents of each are incorporated herein by reference.

### BACKGROUND

### Field

Exemplary embodiments of the present disclosure relate to a plasma processing apparatus, a power supply system, and an etching method.

### Description of Related Art

JP2021-182620 A disclose a technique for improving a processing performance of etching in a plasma processing apparatus.

### SUMMARY

In one exemplary embodiment of the present disclosure, there is provided a plasma processing apparatus including: a chamber; a substrate support that is disposed in the chamber and includes a lower electrode; a gas supply that is configured such that a bimodal gas is supplied into the chamber, the bimodal gas including an etching gas and a deposition gas; a source RF generator that is configured such that a source RF signal is generated to form a plasma from the bimodal gas in the chamber, the source RF signal having a first source power level in a first deposition priority period and a second deposition priority period, and having a second source power level smaller than the first source power level in a first etching priority period and a second etching priority period, the first deposition priority period and the first etching priority period being included in each of a plurality of first sub-cycles in a first sequence, the second deposition priority period and the second etching priority period being included in each of a plurality of second sub-cycles in a second sequence, the first sequence and the second sequence being included in a main cycle, the first deposition priority period being shorter than the second deposition priority period, and the first etching priority period being longer than the second etching priority period; and a bias RF generator that is electrically connected to the lower electrode and is configured such that a bias RF signal is generated, the bias RF signal having a first bias power level in the first deposition priority period and the second deposition priority period, and having a second bias power level larger than the first bias power level in the first etching priority period and the second etching priority period.

### BRIEF DESCRIPTION OF DRAWINGS

FIG. 1 is a diagram for describing a configuration example of a plasma processing apparatus.

FIG. 2 is a diagram for describing a configuration example of a capacitively coupled plasma processing apparatus.

FIG. 3 is a flowchart illustrating the present processing method.

FIG. 4 is a view illustrating an example of a cross-sectional structure of a substrate W provided in step ST1.

FIG. 5 is a flowchart illustrating an example of step ST2.

FIG. 6 is a diagram illustrating an example of supply of a source RF signal, a bias signal, and a processing gas in a cycle CY.

FIG. 7A is a diagram for describing an example of a phenomenon generated in step ST22.

FIG. 7B is a diagram for describing an example of a phenomenon generated in step ST23.

FIG. 8A is a diagram for describing an example of a phenomenon generated in step ST26.

FIG. 8B is a diagram for describing an example of a phenomenon generated in step ST27.

FIG. 9A is a diagram illustrating another example of the source RF signal and the bias signal supplied in the cycle CY.

FIG. 9B is a diagram illustrating another example of the source RF signal and the bias signal supplied in the cycle CY.

FIG. 10 is a diagram illustrating another example of supply of the source RF signal, the bias signal, and the processing gas in the cycle CY.

FIG. 11 is a diagram illustrating another example of supply of the source RF signal, the bias signal, and the processing gas in the cycle CY.

FIG. 12 is a diagram illustrating another example of supply of the source RF signal, the bias signal, and the processing gas in the cycle CY.

FIG. 13 is a flowchart illustrating a method MT.

FIG. 14A is a view illustrating an example of a cross-sectional structure of a substrate W prepared in step ST100.

FIG. 14B is a view illustrating an example of the cross-sectional structure of the substrate W after processing of step ST300.

FIG. 14C is a view illustrating an example of the cross-sectional structure of the substrate W after processing of step ST400.

FIG. 14D is a view illustrating an example of the cross-sectional structure of the substrate W after processing of step ST600.

FIG. 15 is a table illustrating results of the etching of Example 1, Example 2, and Reference Examples 1 to 4.

### DETAILED DESCRIPTION

Hereinafter, each embodiment of the present disclosure will be described.

In one exemplary embodiment, a plasma processing apparatus is provided, the plasma processing apparatus including: a chamber; a substrate support that is disposed in the chamber and includes a lower electrode; a gas supply that is configured such that a bimodal gas is supplied into the chamber, the bimodal gas including an etching gas and a deposition gas; a source RF generator that is configured such that a source RF signal is generated to form a plasma from the bimodal gas in the chamber, the source RF signal having a first source power level in a first deposition priority period and a second deposition priority period, and having a second source power level smaller than the first source power level in a first etching priority period and a second etching priority period, the first deposition priority period and the first etching priority period being included in each of a plurality of first sub-cycles in a first sequence, the second deposition priority period and the second etching priority period being included in each of a plurality of second sub-cycles in a second sequence, the first sequence and the second sequence being included in a main cycle, the first deposition priority period being shorter than the second deposition priority period, and the first etching priority period being longer than the second etching priority period; and a bias RF generator that is electrically connected to the lower electrode and is configured such that a bias RF signal is generated, the bias RF signal having a first bias power level in the first deposition priority period and the second deposition priority period, and having a second bias power level larger than the first bias power level in the first etching priority period and the second etching priority period.

In one exemplary embodiment, the first bias power level is a zero voltage level.

In one exemplary embodiment, a plasma processing apparatus is provided, the plasma processing apparatus including: a chamber; a substrate support that is disposed in the chamber and includes a lower electrode; a gas supply that is configured such that a bimodal gas is supplied into the chamber, the bimodal gas including an etching gas and a deposition gas; an RF generator that is configured such that an RF signal is generated to form a plasma from the bimodal gas in the chamber, the RF signal having a first power level in a first deposition priority period and a second deposition priority period, and having a second power level smaller than the first power level in a first etching priority period and a second etching priority period, the first deposition priority period and the first etching priority period being included in each of a plurality of first sub-cycles in a first sequence, the second deposition priority period and the second etching priority period being included in each of a plurality of second sub-cycles in a second sequence, the first sequence and the second sequence being included in a main cycle, the first deposition priority period being shorter than the second deposition priority period, and the first etching priority period being longer than the second etching priority period; and a voltage pulse generator that is electrically connected to the lower electrode and is configured such that a voltage pulse signal is generated, the voltage pulse signal having a burst of voltage pulses having a first voltage level in the first deposition priority period and the second deposition priority period, and having a second voltage level in the first etching priority period and the second etching priority period, and an absolute value of the second voltage level being larger than an absolute value of the first voltage level.

In one exemplary embodiment, the second voltage level has a negative polarity.

In one exemplary embodiment, the first voltage level is a zero voltage level.

In one exemplary embodiment, there is provided a power supply system including: a first RF generator that is configured to generate a first RF signal, the first RF signal having a first power level in a first period and a second period, and having a second power level smaller than the first power level in a third period and a fourth period, the first period and the third period being included in each of a plurality of first sub-cycles in a first sequence, the second period and the fourth period being included in each of a plurality of second sub-cycles in a second sequence, the first sequence and the second sequence being included in a main cycle, the first period being shorter than the second period, and the third period being longer than the fourth period; and a second RF generator that is configured such that a second RF signal is generated, the second RF signal having a third power level in the first period and the second period, and having a fourth power level larger than the third power level in the third period and the fourth period.

In one exemplary embodiment, there is provided a power supply system including: an RF generator that is configured such that an RF signal is generated, the RF signal having a first power level in a first period and a second period, and having a second power level smaller than the first power level in a third period and a fourth period, the first period and the third period being included in each of a plurality of first sub-cycles in a first sequence, and the second period and the fourth period being included in each of a plurality of second sub-cycles in a second sequence, the first sequence and the second sequence being included in a main cycle, the first period being shorter than the second period, and the third period being longer than the fourth period; and a voltage pulse generator that is configured such that a voltage pulse signal is generated, the voltage pulse signal having a burst of voltage pulses having a first voltage level in the first period and the second period, and having a second voltage level in the third period and the fourth period, and an absolute value of the second voltage level being larger than an absolute value of the first voltage level.

In one exemplary embodiment, there is provided an etching method including: (a) preparing a substrate in a chamber of a plasma processing apparatus, the substrate including a film and a mask on the film; and (b) etching the film including a cycle of supplying a pulse of a source RF signal and a pulse of a bias signal, the cycle including a first period, a second period, a third period, and a fourth period, in the first period, a first deposit being formed on the substrate by a first plasma formed from a first processing gas, in the second period, at least the pulse of the bias signal being supplied to the chamber, and the film being etched by the first plasma, in the third period, a second deposit being formed on the substrate by a second plasma formed from a second processing gas, and in the fourth period, at least the pulse of the bias signal being supplied to the chamber, and the film being etched by the second plasma, in which a ratio of a length of the first period to a length of the second period is different from a ratio of a length of the third period to a length of the fourth period.

In one exemplary embodiment, the cycle includes a first ignition period in which a plasma is formed from the first processing gas by supplying the first processing gas to the chamber and supplying the pulse of the source RF signal before the first period or at the beginning of the first period.

In one exemplary embodiment, the cycle includes a second ignition period in which a plasma is formed from the second processing gas by supplying the second processing gas to the chamber and supplying the pulse of the source RF signal before the third period or at the beginning of the third period.

In one exemplary embodiment, a power level of the source RF signal supplied to the chamber in the cycle is largest in the first ignition period or the second ignition period.

In one exemplary embodiment, the pulse of the source RF signal is supplied to the chamber in the first period and the third period.

In one exemplary embodiment, a power level of the source RF signal in the first period is different from a power level of the source RF signal in the third period.

In one exemplary embodiment, a power level of the bias signal in the second period is different from a power level of the bias signal in the fourth period.

In one exemplary embodiment, a power level of the bias signal supplied to the chamber in the cycle is largest in the second period or the fourth period.

In one exemplary embodiment, the first processing gas is different from the second processing gas.

In one exemplary embodiment, the first processing gas is the same as the second processing gas.

In one exemplary embodiment, a flow rate of the first processing gas is different from a flow rate of the second processing gas.

In one exemplary embodiment, a flow rate of the first processing gas is the same as a flow rate of the second processing gas.

In one exemplary embodiment, in the cycle, after a first cycle including the first period and the second period is repeated once or more, a second cycle including the third period and the fourth period is repeated once or more.

In one exemplary embodiment, a length of a period in which the first cycle is repeated is different from a length of a period in which the second cycle is repeated.

In one exemplary embodiment, a length of a period in which the first cycle is repeated is the same as a length of a period in which the second cycle is repeated.

In one exemplary embodiment, there is provided an etching method including: (a) preparing a substrate in a chamber of a plasma processing apparatus, the substrate including a film and a mask on the film; and (b) etching the film including a cycle of supplying a pulse of a source RF signal and a pulse of a bias signal, the cycle including a first period, a second period, a third period, and a fourth period, in the first period, at least the pulse of the source RF signal being supplied to the chamber, and a first deposit being formed on the substrate by a first plasma formed from a first processing gas, in the second period, at least the pulse of the bias signal being supplied to the chamber, and the film being etched by the first plasma, in the third period, at least the pulse of the source RF signal being supplied to the chamber, and a second deposit being formed on the substrate by a second plasma formed from a second processing gas, and in the fourth period, at least the pulse of the bias signal being supplied to the chamber, and the film being etched by the second plasma, in which a power level of the source RF signal supplied in the first period is different from a power level of the source RF signal supplied in the third period, or a power level of the bias signal supplied in the second period is different from a power level of the bias signal supplied in the fourth period.

In one exemplary embodiment, there is provided an etching method including: (a) preparing a substrate in a chamber of a plasma processing apparatus, the substrate including a film and a mask on the film; and (b) etching the film including a cycle of supplying a pulse of a source RF signal and a pulse of a bias signal, the cycle including a first period, a second period, a third period, and a fourth period, in the first period, a first deposit being formed on the substrate by a first plasma formed from a first processing gas, in the second period, at least the pulse of the bias signal being supplied to the chamber, and the film being etched by the first plasma formed from the first processing gas, in the third period, a second deposit being formed on the substrate by a second plasma formed from a second processing gas, and in the fourth period, at least the pulse of the bias signal being supplied to the chamber, and the film being etched by a plasma formed from the second processing gas, in which the first processing gas supplied in the first period has a different flow rate from the second processing gas supplied in the third period, or the first processing gas supplied in the second period has a different flow rate from the second processing gas supplied in the fourth period.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### <Configuration Example of Plasma Processing Apparatus>

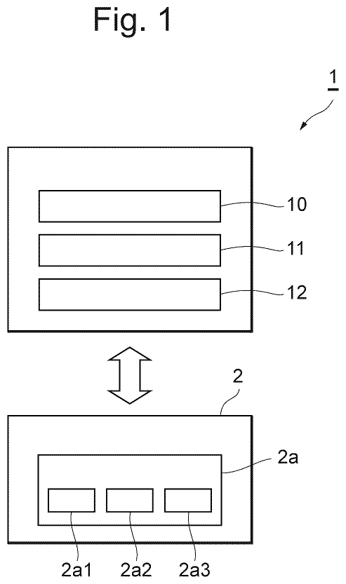

FIG. 1 is a diagram for describing a configuration example of a plasma processing apparatus. In an embodiment, a plasma processing apparatus 1 is an example of a substrate processing apparatus. The plasma processing apparatus 1 includes a controller 2, a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20 which is described later, and the gas exhaust port is connected to an exhaust system 40 which is described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or all of the controller 2 may be configured as a system outside the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with each element of the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

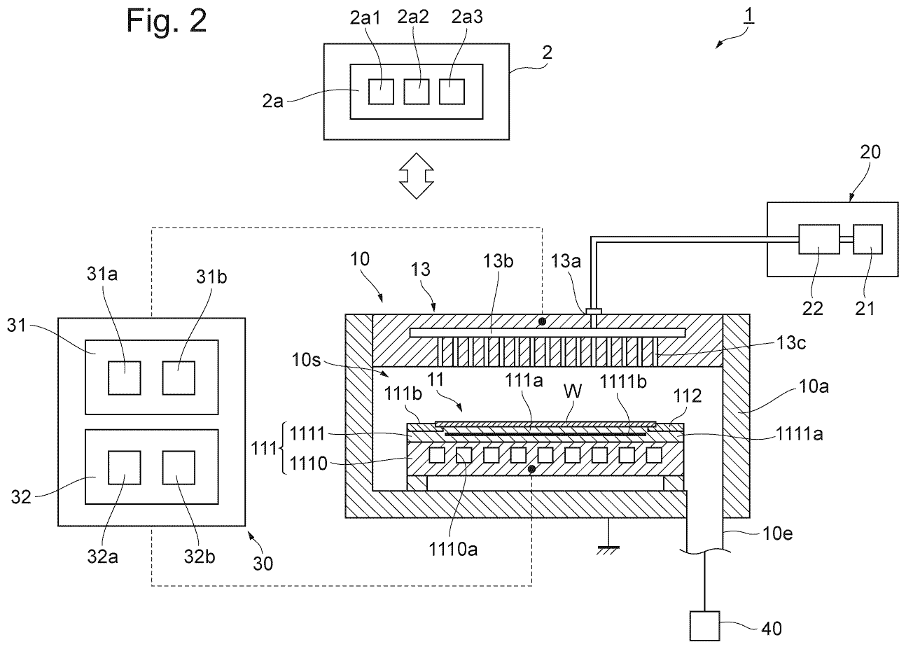

Hereinafter, a configuration example of a capacitively coupled plasma processing apparatus as an example of the plasma processing apparatus 1 will be described. FIG. 2 is a diagram for describing a configuration example of the capacitively coupled plasma processing apparatus.

The capacitively coupled plasma processing apparatus 1 includes the controller 2, the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator (source RF generator) 31a and a second RF generator (bias RF generator) 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). A frequency of the bias RF signal may be the same as or different from a frequency of the source RF signal. In an embodiment, the bias RF signal has the frequency lower than the frequency of the source RF signal. In an embodiment, the bias RF signal has a frequency in a range of 100 kHz to 60 MHz. In an embodiment, the second RF generator 31b may be configured to generate a plurality of bias RF signals having different frequencies. The generated one or plurality of bias RF signals is supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate a first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positively-polarized voltage pulses and one or a plurality of negatively-polarized voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. A pressure in the plasma processing space 10s is regulated by the pressure regulating valve. The vacuum pump may include a turbo molecular pump, a dry pump, or a combination thereof.

### <Example of Plasma Processing Method>

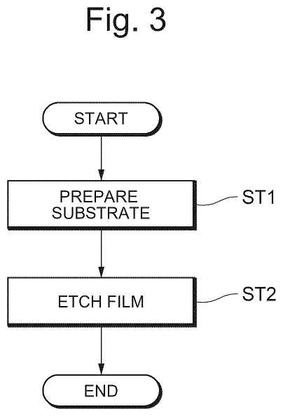

FIG. 3 is a flowchart illustrating an etching method according to one exemplary embodiment (hereinafter, also referred to as “the present processing method”). As illustrated in FIG. 3, the present processing method includes step ST1 of preparing a substrate and step ST2 of etching a film. The processing in each step may be performed by the above-described plasma processing apparatus 1. In the following, a case where the controller 2 controls each unit of the capacitively coupled plasma processing apparatus 1 (see FIG. 2) to execute the present processing method on the substrate W will be described as an example.

### (Step ST1: Preparation of Substrate)

In step ST1, the substrate W is prepared in the plasma processing space 10s of the plasma processing apparatus 1. The substrate W is carried into the chamber 10 by a transport arm and is placed on the center region 111a of the substrate support 11. The substrate W is adsorbed and held on the substrate support 11 by the electrostatic chuck 1111.

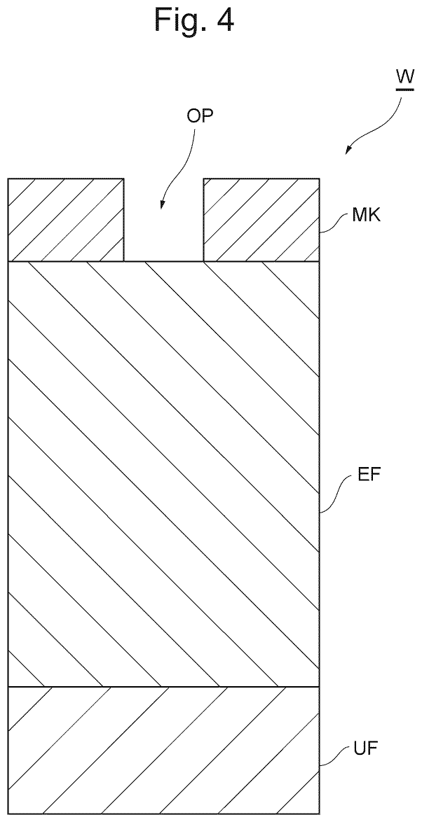

FIG. 4 is a view illustrating an example of a cross-sectional structure of the substrate W prepared in step ST1. The substrate W has a film EF and a mask MK. The substrate W may further include an underlying film UF. The substrate W may be used for manufacturing a semiconductor device. For example, the semiconductor device includes a semiconductor memory device such as a DRAM and a 3D-NAND flash memory.

In an example, the underlying film UF may be a silicon wafer, an organic film, a dielectric film, a metal film, a semiconductor film, or a film stack thereof, which is formed on a silicon wafer. In an embodiment, the underlying film UF includes at least one selected from the group consisting of a silicon-containing film, a carbon-containing film, and a metal-containing film.

The film EF is a film to be etched in the present processing method. The film EF may be configured of one film, or may be configured of a plurality of films stacked. In an embodiment, the film EF is an organic film, a dielectric film, a semiconductor film, a metal film, or a film stack thereof. For example, the film EF may be configured by stacking one or a plurality of films such as a silicon-containing film, a carbon-containing film, a spin-on-glass (SOG) film, and a Si-containing antireflective coating (SiARC). In an embodiment, the film EF is the silicon-containing film. In an example, the silicon-containing film is configured by alternately stacking a silicon oxide film and a silicon nitride film. In an example, the silicon-containing film is configured by alternately stacking a silicon oxide film and a polycrystalline silicon film. In an example, the silicon-containing film is a film stack including the silicon nitride film, the silicon oxide film, and the polycrystalline silicon film. In an example, the silicon-containing film includes a silicon carbonitride film.

The mask MK has a pattern transferred to the film EF by etching. As illustrated in FIG. 4, the mask MK defines at least one opening OP on the mask MK. The opening OP is a space on the mask MK and is surrounded by a side wall of the mask MK. That is, the upper surface of the film EF has a region covered by the mask MK and a region exposed at the bottom portion of the opening OP.

The opening OP may have any shape in a plan view of the substrate W, that is, in a case where the substrate W is viewed in a direction from top to bottom in FIG. 4. The shape may be, for example, a circle, an ellipse, a rectangle, a line, or a shape in which one or more of these are combined. The mask MK may have a plurality of side walls, and the plurality of side walls may define a plurality of the openings OP. The plurality of openings OP may each have a linear shape and may be arranged at regular intervals to form a line & space pattern. In addition, the plurality of openings OP may each have a hole shape to form an array pattern.

The mask MK may be formed of a material having an etching rate with respect to the plasma formed in step ST2 lower than that of the film EF. In an embodiment, the mask MK is an organic film mask. In an example, the mask MK is an amorphous carbon film, a photoresist film, or a spin-on carbon (SOC) film. In an example, the photoresist film may contain a metal such as tin. In an embodiment, the mask MK is a metal-containing mask. In an example, the mask MK may be a metal-containing film containing at least one metal selected from the group consisting of tin, tungsten, molybdenum, and titanium. The mask MK may be a single-layer mask consisting of one layer or a multi-layer mask consisting of two or more layers.

Each film (the underlying film UF, the film EF, or the mask MK) constituting the substrate W may be formed by a CVD method, an ALD method, a spin coating method, and the like, respectively. The mask MK or the opening OP of the mask MK may be formed by etching the mask MK, or may be formed by lithography. Each film may be a flat film or a film having unevenness, respectively. The substrate W may further have another film under the underlying film UF. In this case, a concave portion having a shape corresponding to the opening OP may be formed in the film EF and the underlying film UF, and the other film may be used as the mask for etching.

At least a part of a process of forming each film of the substrate W may be performed in the space of the plasma processing chamber 10. In an example, the step of etching the mask MK to form the opening OP may be executed in the plasma processing chamber 10. That is, the etching of the opening OP and the film EF in step ST2 described later may be continuously executed in the same chamber. In addition, the substrate W may be prepared by forming all of each film of the substrate W by an external apparatus or the chamber of the plasma processing apparatus 1, and then carrying the substrate W into the plasma processing space 10s of the plasma processing apparatus 1, and disposing the substrate W in the center region 111a of the substrate support 11.

In an embodiment, after the substrate W is provided in the center region 111a of the substrate support 11, the temperature of the substrate support 11 is adjusted to the set temperature by the temperature-controlled module. In an example, adjusting or maintaining the temperature of the substrate support 11 includes setting the temperature of the heat transfer fluid flowing through the flow passage 1110a and the heater temperature to a set temperature or to a temperature different from the set temperature. The timing at which the heat transfer fluid begins to flow in the flow passage 1110a may be before, after, or at the same time as the time at which the substrate W is placed on the substrate support 11. In addition, the temperature of the substrate support 11 may be adjusted to the set temperature before step ST11. That is, the substrate W may be provided on the substrate support 11 after the temperature of the substrate support 11 is adjusted to the set temperature. In an embodiment, the temperature of the substrate support 11 may be maintained at the set temperature or may be changed in the subsequent steps.

### (Step ST2)

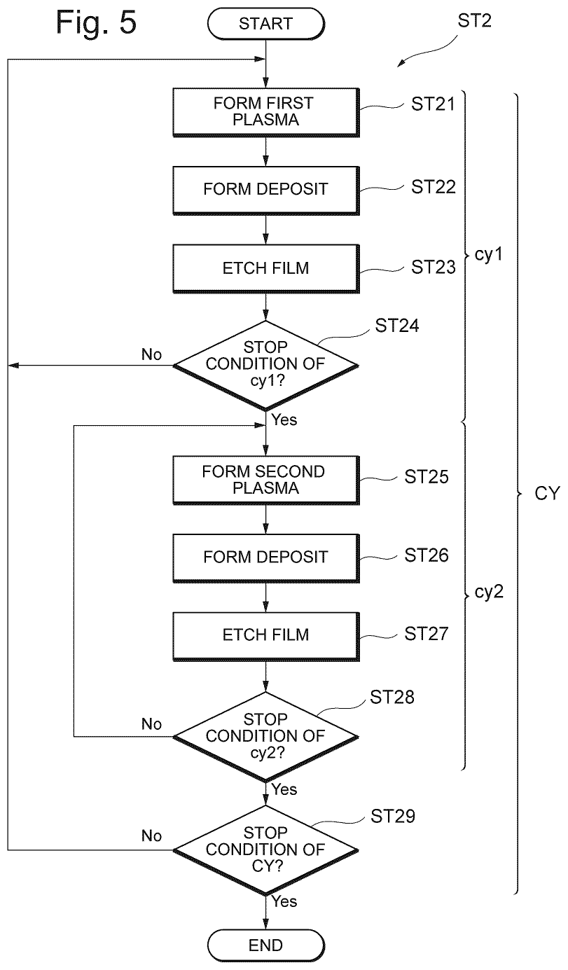

FIG. 5 is a flowchart illustrating an example of step ST2. In step ST2, the film EF is etched. As illustrated in FIG. 5, in step ST2, a cycle CY (step ST21 to step ST28) is repeated until a stop condition thereof is satisfied (step ST29: Yes). One cycle CY includes a first cycle cy1 (step ST21 to step ST24) and a second cycle cy2 (step ST25 to step ST28). In the cycle CY, after the first cycle cy1 is repeated until the stop condition thereof is satisfied (step ST24: Yes), the second cycle cy2 is repeated until the stop condition thereof is satisfied (step ST28: Yes).

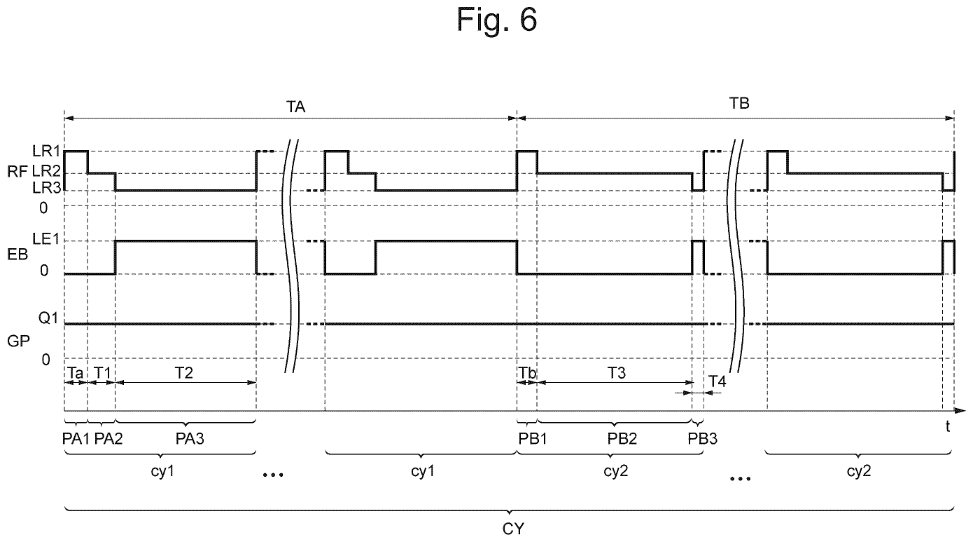

FIG. 6 is a diagram illustrating an example of the supply of the source RF signal, the bias signal, and the processing gas in the cycle CY. In an embodiment, the bias signal is the bias RF signal supplied from the second RF generator 31b. In an embodiment, the bias signal is a bias DC signal supplied from the DC generator 32a. In FIG. 6, a horizontal axis is time. The “RF” on a vertical axis of FIG. 6 indicates a power level of the source RF signal. In an embodiment, the power level of the source RF signal is an effective value of the power of the source RF signal. The “EB” on the vertical axis of FIG. 6 indicates the power level of the bias signal. In an embodiment, the power level of the bias signal is an effective value of the power of the bias RF signal. In an embodiment, the power level of the bias signal is an absolute value of a voltage of the bias DC signal. The “GP” on the vertical axis of FIG. 6 indicates the flow rate of the processing gas (the first processing gas or the second processing gas). As illustrated in FIG. 6, the source RF signal and the bias signal are each pulsed. In a case where the bias signal is the bias DC signal, in FIG. 6, the bias DC signal may have a waveform of a rectangle, a trapezoid, a triangle, or a combination thereof, and a relationship of LR1>LR2>LR3>0 is established. In addition, a relationship of LE1>0 is established. In FIG. 6, “PA1” to “PA3” of the first cycle cy1 correspond to step ST21 to step ST23 of FIG. 5, respectively. “PB1” to “PB3” of the second cycle cy2 correspond to step ST25 to step ST27 of FIG. 5, respectively. In an embodiment, a single period of the cycle CY is 1 second to 30 seconds.

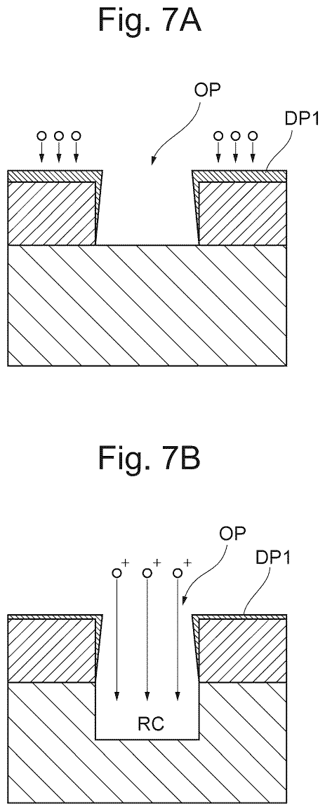

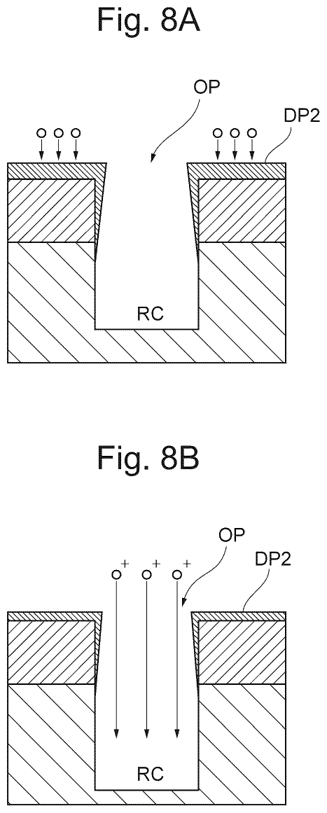

FIGS. 7A and 7B are diagrams for describing an example of a phenomenon generated in step ST22 and step ST23, respectively. In addition, FIGS. 8A and 8B are diagrams for describing an example of a phenomenon generated in step ST26 and step ST27, respectively.

Hereinafter, each step of the cycle CY will be described with reference to FIGS. 5 to 8. As illustrated in FIGS. 5 and 6, in the cycle CY, the first cycle cy1 (step ST21 to step ST24) is repeatedly executed until the stop condition thereof is satisfied, and then the second cycle cy2 (step ST25 to step ST28) is repeatedly executed until the stop condition thereof is satisfied.

First, the first cycle cy1 will be described. First, in step ST21, a first plasma is formed. Specifically, the first processing gas is supplied into the plasma processing space 10s from the gas supply 20. In addition, the source RF signal is supplied to the lower electrode of the substrate support 11 and/or the upper electrode of the shower head 13. As a result, the first plasma is formed in the plasma processing chamber 10, and active species such as radicals or ions are generated from the gas components of the first processing gas. As illustrated in “PA1” of FIG. 6, the power level of the source RF signal supplied in step ST21 is LR1. In an embodiment, the power level LR1 is the highest among the power levels of the source RF signals supplied in the cycle CY. In addition, the power level of the bias signal in step ST21 is zero (that is, the bias signal is not supplied). A length of the period in which step ST21 is executed (a period indicated by “Ta” in FIG. 6, and hereinafter, also referred to as a “first ignition period Ta”) may be appropriately set, and in an example, the length is 10 μs to 1 ms.

The first processing gas includes a gas having depositability. In an embodiment, the gas having the depositability includes a fluorine-containing gas. The fluorine-containing gas may include a gas component containing fluorine and carbon. This gas component may be a fluorocarbon gas such as C₄F₈ gas. That is, the fluorine-containing gas may be a fluorocarbon gas. This gas component may include hydrofluorocarbon gas in addition to or instead of the fluorocarbon gas. The first processing gas may further include one or more of a nitrogen gas, an oxygen-containing gas (for example, an oxygen gas), and a noble gas (for example, an Ar gas). As illustrated in “PA1” of FIG. 6, the flow rate of the first processing gas supplied in step ST21 is Q1. In an embodiment, the first processing gas includes a bimodal gas. The bimodal gas includes an etching gas and a deposition gas. The etching gas is, for example, a CF₄ gas. The deposition gas is, for example, C₄F₈ gas. The bimodal gas may further include a nitrogen gas, an oxygen-containing gas (for example, an oxygen gas), and a noble gas (for example, an Ar gas).

Next, in step ST22, a deposit is formed on the substrate W. As in step ST21, the first processing gas is supplied into the plasma processing space 10s at a flow rate Q1, and the source RF signal is supplied to the lower electrode of the substrate support 11 and/or the upper electrode of the shower head 13. As illustrated in “PA2” of FIG. 6, the power level of the source RF signal in step ST22 is LR2 (<LR1). In addition, the power level of the bias signal in step ST22 is zero (that is, the bias signal is not supplied). As a result, as illustrated in FIG. 7A, a part of the active species in the plasma is deposited on the substrate W to form a deposit DP1. In an embodiment, the deposit DP1 is selectively deposited on the mask MK. The deposit DP1 may function as a protective film against etching of the mask MK. A length of a period in which step ST22 is executed (a period indicated by “T1” of FIG. 6, and hereinafter, also referred to as a “first period T1”) may be appropriately set, and in an example, the length is 10 μs to 10 ms.

Next, in step ST23, the film EF is etched. As in step ST21, the first processing gas is supplied into the plasma processing space 10s at a flow rate Q1, and the source RF signal is supplied to the lower electrode of the substrate support 11 and/or the upper electrode of the shower head 13. In step ST23, a bias signal is further supplied to the lower electrode. As illustrated in “PA3” of FIG. 6, the power level of the source RF signal in step ST23 is LR3 (<LR2). In addition, the power level of the bias signal is LE1 (>0). As a result, a bias potential is generated between the plasma and the substrate W, and ions in the plasma are attracted to the substrate W as illustrated in FIG. 7B. As a result, a portion of the film EF that is not covered by the mask MK (a portion exposed in the opening OP) is etched in the depth direction, and a concave portion RC is formed. A length of the period in which step ST23 is executed (a period indicated by “T2” in FIG. 6, hereinafter, also referred to as a “second period T2”) may be appropriately set, and in an example, the length is 10 μs to 10 ms.

In the example illustrated in FIG. 6, in the first cycle cy1, the second period T2 in which the film EF is etched is longer than the first period T1 in which the deposit DP1 is formed. That is, in this example, the first cycle cy1 is a process in which etching is priority as compared with the second cycle cy2 described later.

Next, in step ST24, it is determined whether a stop condition of the first cycle cy1 is satisfied. In a case where the stop condition is satisfied, the first cycle cy1 is ended, and the processing proceeds to step ST25 to execute the second cycle cy2. In a case where the stop condition is not satisfied, the processing returns to step ST21, and the first cycle cy1 is repeated again. The stop condition may be set based on, for example, the number of cycles or time. For example, the number of times or the time for which the first cycle cy1 is executed may be counted, and whether the stop condition is satisfied may be determined depending on whether the number of times or the time reaches the number of cycles or the time set in advance. In the first cycle cy1 of the second or subsequent time, step ST21 may not be executed. The frequency of the first cycle cy1 may be appropriately set, and in an example, the frequency is 0.01 kHz to 100 KHz. A length of the period in which the first cycle cy1 is repeated (time indicated by “TA” in FIG. 6) may be appropriately set, and in an example, the length is 0.1 seconds to 30 seconds.

Next, the second cycle cy2 will be described. First, in step ST25, the second plasma is formed from the second processing gas. Step ST25 may be executed in the same manner as step ST21. The second processing gas includes a gas having depositability, similarly to the first processing gas. As illustrated in “PB1” of FIG. 6, the power level of the source RF signal supplied in step ST25 may be the same LR1 as that in step ST21. In addition, as in step ST21, the power level of the bias signal may be zero (that is, the bias signal may not be supplied). In addition, the flow rate of the second processing gas may be Q1 as in the first processing gas. The type of gas constituting the second processing gas and each partial pressure thereof may be the same as those of the first processing gas, or may be partially or entirely different therefrom. A length of the period in which step ST25 is executed (a period indicated by “Tb” of FIG. 6, and hereinafter, also referred to as a “second ignition period Tb”) may be the same as or different from the length of the first ignition period Ta. In an embodiment, the second processing gas includes a bimodal gas. The bimodal gas includes an etching gas and a deposition gas. The etching gas is, for example, a CF₄ gas. The deposition gas is, for example, C₄F₈ gas. The bimodal gas may further include a nitrogen gas, an oxygen-containing gas (for example, an oxygen gas), and a noble gas (for example, an Ar gas).

Next, in step ST26, the deposit is formed on the substrate W. Step ST26 may be executed in the same manner as step ST22. As illustrated in “PB2” of FIG. 6, the power level of the source RF signal in step ST26 may be LR2 (<LR1) as in step ST22. In addition, the power level of the bias signal may be zero (that is, the bias signal may not be supplied). As a result, as illustrated in FIG. 8A, a part of the active species in the plasma is deposited on the substrate W to form a deposit DP2. In an embodiment, the deposit DP2 is selectively deposited on the mask MK. The deposit DP2 may function as the protective film against etching of the mask MK. A length of the period in which step ST26 is executed (a period indicated by “T3” of FIG. 6, hereinafter, also referred to as a “third period T3”) may be appropriately set, and in an example, the length is 10 μs to 10 ms.

Next, in step ST27, the film EF is etched. Step ST27 may be executed in the same manner as step ST23. As illustrated in “PB3” of FIG. 6, the power level of the source RF signal in step ST27 may be LR3 (<LR2) as in step ST23, and the power level of the bias signal may be “LE1” (>0). As a result, the bias potential is generated between the plasma and the substrate W. Then, as illustrated in FIG. 8B, the film EF is further etched, and a depth of the concave portion RC increases. A length of the period in which step ST27 is executed (a period indicated by “T4” of FIG. 6, and hereinafter, also referred to as a “fourth period T4”) may be appropriately set, and in an example, the length is 10 μs to 10 ms.

In the example illustrated in FIG. 6, in the second cycle cy2, the third period T3 for forming the deposit DP2 is longer than the fourth period T4 for etching the film EF. That is, in this example, the second cycle cy2 is a process in which the formation of the deposit is priority as compared with the first cycle cy1.

Next, in step ST28, it is determined whether the stop condition of the second cycle cy2 is satisfied. In a case where the stop condition is not satisfied, the processing returns to step ST25, and the second cycle cy2 is repeated again. The stop condition may be appropriately set as in step ST24, and may be set, for example, based on the number of cycles or time. In the second cycle cy2 that is the second or subsequent time, step ST25 may or may not be executed. The frequency of the second cycle cy2 may be appropriately set, and in an example, the frequency is 0.01 kHz to 100 KHz. The frequency of the second cycle cy2 may be the same as or different from the frequency of the first cycle cy1. The length of the period in which the second cycle cy2 is repeated (time indicated by “TB” in FIG. 6) may be appropriately set, and in an example, the length is 0.1 seconds to 30 seconds.

In step ST28, in a case where the stop condition is satisfied, the second cycle cy2 is ended, and step ST29 is executed. Then, in step ST29, it is determined whether the stop condition of the cycle CY is satisfied. In a case where the stop condition of the cycle CY is not satisfied, the current cycle CY is ended, the processing returns to step ST21, and the next cycle CY is started.

The stop condition of the cycle CY may be set based on, for example, the number of cycles or time. For example, the number of times or the time for which the cycle CY is executed may be counted, and whether the stop condition is satisfied may be determined based on whether the number of times or the time reaches the number of cycles or the time set in advance. In addition, the stop condition of the cycle CY may be a condition regarding the dimension of the concave portion RC formed in the film EF by etching. That is, in step ST29, it may be determined whether the stop condition is satisfied by determining whether the depth of the concave portion RC and the width of the bottom portion of the concave portion RC formed in the film EF reach a given value or range. In a case where the stop condition is satisfied, step ST2 is ended.

In an embodiment, a ratio of the length of the first period T1 to the length of the second period T2 of the first cycle cy1 (hereinafter, also referred to as “T2/T1”) is different from a ratio of the length of the third period T3 to the length of the fourth period T4 of the second cycle cy2 (hereinafter, also referred to as “T4/T3”). T2/T1 or T4/T3 is a ratio of the formation time of the deposit to the etching time. Since T2/T1 and T4/T3 are different from each other, a balance between the formation of the deposit and the etching is different between the first cycle cy1 and the second cycle cy2. For example, in the example illustrated in FIG. 6, since T2/T1>T4/T3, the first cycle cy1 is an etching-based process, and the second cycle cy2 is a deposit formation-based process when the first cycle cy1 and the second cycle cy2 are compared with each other.

In an embodiment, the plasma processing apparatus 1 includes a source RF generator 31a and a bias RF generator 31b. The source RF generator 31a is configured such that the source RF signal is generated to form the plasma from the bimodal gas in the chamber 10. The bias RF generator 31b is electrically connected to the lower electrode and is configured such that the bias RF signal is generated. In the example illustrated in FIG. 6, the source RF signal RF has a first source power level LR2 in a first deposition priority period T1 and a second deposition priority period T3, and has a second source power level LR3 in a first etching priority period T2 and a second etching priority period T4. The second source power level LR3 is smaller than the first source power level LR2. The bias RF signal EB has a first bias power level in the first deposition priority period T1 and the second deposition priority period T3, and has a second bias power level LE1 in the first etching priority period T2 and the second etching priority period T4. The second bias power level LE1 is larger than the first bias power level. In an embodiment, the first bias power level is a zero voltage level. In an embodiment, the first bias power level is a voltage level larger than zero. Then, the first deposition priority period T1 and the first etching priority period T2 are included in each of a plurality of first sub-cycles cy1 in a first sequence TA. The second deposition priority period T3 and the second etching priority period T4 are included in each of a plurality of second sub-cycles cy2 in a second sequence TB. In an embodiment, the main cycle CY is repeated. In an embodiment, the main cycle CY includes one or a plurality of sequences, and each sequence includes a plurality of sub-cycles. That is, the sub-cycle is repeated in the sequence. In an embodiment, one or the plurality of sequences includes the first sequence TA and the second sequence TB, the first sequence TA includes the plurality of first sub-cycles cy1, and the second sequence TB includes the plurality of second sub-cycles cy2. In an embodiment, the main cycle CY includes the first sequence TA and the second sequence TB. In an embodiment, the first sequence TA and the second sequence TB are alternately repeated. In an embodiment, the first deposition priority period T1 is shorter than the second deposition priority period T3, and the first etching priority period T2 is longer than the second etching priority period T4. In an embodiment, the main cycle CY includes first to Nth (N is a natural number of 2 or more) sequences, and a length of the etching priority period is adjusted with respect to a length of the deposition priority period between each sequence and the next sequence.

In an embodiment, the plasma processing apparatus 1 includes the source RF generator 31a and the voltage pulse generator. The RF generator 31a is configured such that the RF signal is generated to form the plasma from the bimodal gas in the chamber 10. The voltage pulse generator is electrically connected to the lower electrode and is configured such that the voltage pulse signal is generated. In the example illustrated in FIG. 6, the RF signal RF has the first power level LR2 in the first deposition priority period T1 and the second deposition priority period T3, and has the second power level LR3 in the first etching priority period T2 and the second etching priority period T4. The second power level LR3 is smaller than the first power level LR2. The voltage pulse signal EB has a burst (sequence) of voltage pulses having the first voltage level in the first deposition priority period T1 and the second deposition priority period T3, and having a second voltage level LE1 in the first etching priority period T2 and the second etching priority period T4. An absolute value of the second voltage level LE1 is larger than an absolute value of the first voltage level. In an embodiment, the second voltage level LE1 has a negative polarity. In an embodiment, the first voltage level is a zero voltage level. In an embodiment, the first voltage level may have a voltage level larger than zero. In an embodiment, the voltage pulse signal EB has a burst (sequence) of voltage pulses having the first voltage level in the first deposition priority period T1 and the second deposition priority period T3. In this case, the absolute value of the first voltage level is smaller than the absolute value of the second voltage level LE1. Then, the first deposition priority period T1 and the first etching priority period T2 are included in each of a plurality of first sub-cycles cy1 in a first sequence TA. The second deposition priority period T3 and the second etching priority period T4 are included in each of a plurality of second sub-cycles cy2 in a second sequence TB. In an embodiment, the main cycle CY is repeated. In an embodiment, the main cycle CY includes one or a plurality of sequences, and each sequence includes a plurality of sub-cycles. That is, the sub-cycle is repeated in the sequence. In an embodiment, one or the plurality of sequences includes the first sequence TA and the second sequence TB, the first sequence TA includes the plurality of first sub-cycles cy1, and the second sequence TB includes the plurality of second sub-cycles cy2. In an embodiment, the main cycle CY includes the first sequence TA and the second sequence TB. In an embodiment, the first sequence TA and the second sequence TB are alternately repeated. In an embodiment, the first deposition priority period T1 is shorter than the second deposition priority period T3, and the first etching priority period T2 is longer than the second etching priority period T4. In an embodiment, the main cycle CY includes first to Nth (N is a natural number of 2 or more) sequences, and a length of the etching priority period is adjusted with respect to a length of the deposition priority period between each sequence and the next sequence.

In an embodiment, the power supply system includes the first RF generator 31a and the second RF generator 31b. The first RF generator 31a is configured such that the first RF signal is generated. The second RF generator 31b is configured such that the second RF signal is generated. In the example illustrated in FIG. 6, the first RF signal RF has the first power level LR2 in the first period T1 and the second period T2, and has the second power level LR3 in the third period T3 and the fourth period T4. The second power level LR3 is smaller than the first power level LR2. The second RF signal EB has a third power level in the first period T1 and the second period T2 and has a fourth power level LE1 in the third period T3 and the fourth period T4. The fourth power level LE1 is larger than the third power level. In an embodiment, the third power level is the zero voltage level. In an embodiment, the third power level is a voltage level larger than zero. Then, the first period T1 and the third period T3 are included in each of the plurality of first sub-cycles cy1 in the first sequence TA. The second period T2 and the fourth period T4 are included in each of the plurality of second sub-cycles cy2 in the second sequence TB. In an embodiment, the main cycle CY is repeated. In an embodiment, the main cycle CY includes one or a plurality of sequences, and each sequence includes a plurality of sub-cycles. That is, the sub-cycle is repeated in the sequence. In an embodiment, one or the plurality of sequences includes the first sequence TA and the second sequence TB, the first sequence TA includes the plurality of first sub-cycles cy1, and the second sequence TB includes the plurality of second sub-cycles cy2. In an embodiment, the main cycle CY includes the first sequence TA and the second sequence TB. In an embodiment, the first sequence TA and the second sequence TB are alternately repeated. In an embodiment, the first period T1 is shorter than the second period T2, and the third period T3 is longer than the fourth period T4. In an embodiment, the main cycle CY includes first to Nth (N is a natural number of 2 or more) sequences, and a length of the etching priority period is adjusted with respect to a length of the deposition priority period between each sequence and the next sequence.

In an embodiment, the power supply system includes the RF generator 31a and the voltage pulse generator. The RF generator 31a is configured such that the RF signal is generated. The voltage pulse generator is configured such that the voltage pulse signal is generated. In the example illustrated in FIG. 6, the RF signal has the first power level LR2 in the first period T1 and the second period T2, and has the second power level LR3 in the third period T3 and the fourth period T4. The second power level LR3 is smaller than the first power level LR2. The voltage pulse signal EB has the burst (sequence) of voltage pulses having the first voltage level in the first period T1 and the second period T3, and having the second voltage level LE1 in the third period T3 and the fourth period T4. An absolute value of the second voltage level LE1 is larger than an absolute value of the first voltage level. In an embodiment, the second voltage level LE1 has a negative polarity. In an embodiment, the first voltage level is a zero voltage level. In an embodiment, the first voltage level may have a voltage level larger than zero. In an embodiment, the voltage pulse signal EB has the burst (sequence) of voltage pulses having the first voltage level in the first period T1 and the second period T2. In this case, the absolute value of the first voltage level is smaller than the absolute value of the second voltage level LE1. Then, the first period T1 and the third period T3 are included in each of the plurality of first sub-cycles cy1 in the first sequence TA. The second period T3 and the fourth period T4 are included in each of the plurality of second sub-cycles cy2 in the second sequence TB. In an embodiment, the main cycle CY is repeated. In an embodiment, the main cycle CY includes one or a plurality of sequences, and each sequence includes a plurality of sub-cycles. That is, the sub-cycle is repeated in the sequence. In an embodiment, one or the plurality of sequences includes the first sequence TA and the second sequence TB, the first sequence TA includes the plurality of first sub-cycles cy1, and the second sequence TB includes the plurality of second sub-cycles cy2. In an embodiment, the main cycle CY includes the first sequence TA and the second sequence TB. In an embodiment, the first sequence TA and the second sequence TB are alternately repeated. In an embodiment, the first period T1 is shorter than the second period T2, and the third period T3 is longer than the fourth period T4. In an embodiment, the main cycle CY includes first to Nth (N is a natural number of 2 or more) sequences, and a length of the etching priority period is adjusted with respect to a length of the deposition priority period between each sequence and the next sequence.

According to the present processing method, the controllability of etching can be improved. According to the etching by the present processing method, it is possible to obtain a desired etching shape (suppression of bowing, removal property) while suppressing a decrease in the selectivity ratio with respect to the mask.

The source RF signal, the bias signal, and the processing gas supplied in the cycle CY are not limited to the example illustrated in FIG. 6, and various aspects can be adopted.

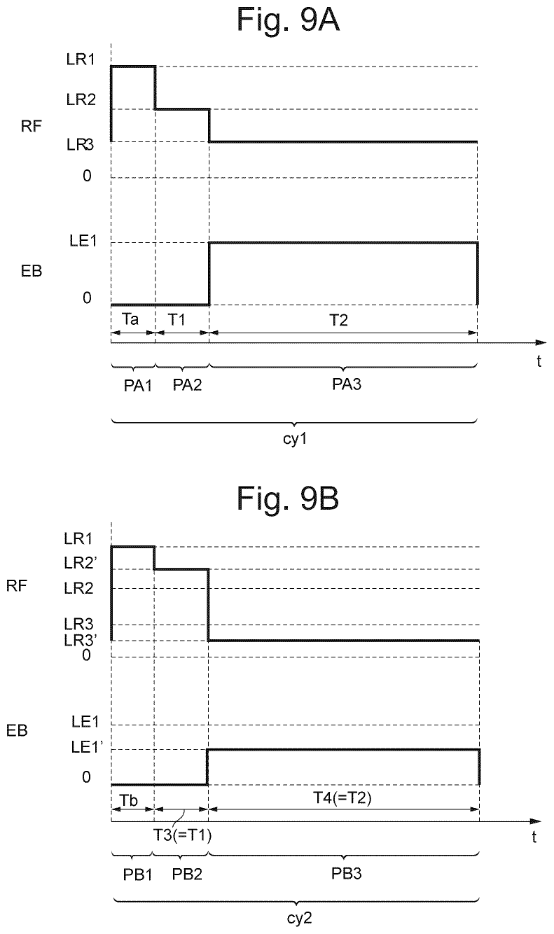

FIGS. 9A and 9B are diagrams illustrating other examples of the source RF signal and the bias signal supplied in the cycle CY. FIG. 9A is an example of the source RF signal and the bias signal supplied in the first cycle cy1, and FIG. 9B is an example of the source RF signal and the bias signal supplied in the second cycle cy2. The horizontal axis and the vertical axis in FIG. 9 are the same as those in FIG. 6.

In this example, the lengths of the third period T3 and the fourth period T4 of the second cycle cy2 are the same as the lengths of the first period T1 and the second period T2 of the first cycle cy1, respectively. That is, T2/T1 and T4/T3 are the same. On the other hand, in this example, the power levels of the source RF signal and the bias signal supplied in the second cycle cy2 are different from the power levels of the source RF signal and the bias signal supplied in the first cycle cy1.

That is, as illustrated in “PA2” of FIG. 9A, the power level of the source RF signal supplied in the first period T1 (step ST22) of the first cycle cy1 is LR2. On the other hand, as illustrated in “PB2” of FIG. 9B, the power level of the source RF signal supplied in the third period T3 (step ST26) of the second cycle cy2 is LR2′ (>LR2). In addition, as illustrated in “PA3” of FIG. 9A, the power levels of the source RF signal and the bias signal supplied in the second period T2 (step ST23) of the first cycle cy1 are LR2 and LE1, respectively. On the other hand, as illustrated in “PB3” of FIG. 9B, the power levels of the source RF signal and the bias signal supplied in the second period T2 (step ST27) of the first cycle cy1 are LR3′ (<LR3) and LE1′ (<LE1), respectively. As a result, in the second cycle cy2, the amount of the deposit formation is increased and the amount of etching is decreased as compared with the first cycle cy1. That is, T2/T1 and T4/T3 are the same, but the balance between the formation of the deposit and the etching is different between the first cycle cy1 and the second cycle cy2. Therefore, even in the examples illustrated in FIGS. 9A and 9B, the controllability of the etching can be improved.

In an embodiment, the power levels of the source RF signals are different between the first period T1 (step ST22) and the third period T3 (step ST26). The source RF signal may not be supplied in the first period T1 (step ST22) and/or the third period T3 (step ST26). In an embodiment, the bias signal may be supplied in the first period T1 (step ST22) and/or the third period T3 (step ST26). The power level of the bias signal in this case may be smaller than LE1. In a case where the source RF signal is supplied in the first period T1 (step ST22) and the third period T3 (step ST26), the power levels of both signals may be the same or different from each other.

In an embodiment, the power levels of the source RF signals are different in the second period T2 (step ST23) and the fourth period T4 (step ST27). In an embodiment, the source RF signal may not be supplied in the second period T2 (step ST23) and/or the fourth period T4 (step ST27) (that is, the power level LR3 of the source RF signal may be zero).

The magnitude relationship between the power levels of the source RF signals in the first ignition period (step ST21), the first period T1 (step ST22), and the second period T2 of the first cycle cy1 is not limited to the example illustrated in FIG. 6, and may be appropriately set. For example, the power level of the source RF signal in the first period T1 (step ST22) and/or the second period T2 may be set to be the highest. In addition, for example, the power levels of the source RF signals in the first ignition period and the first period T1 may be the same. The power level of the source RF signal supplied in the second cycle cy2 may also be appropriately set in the same manner.

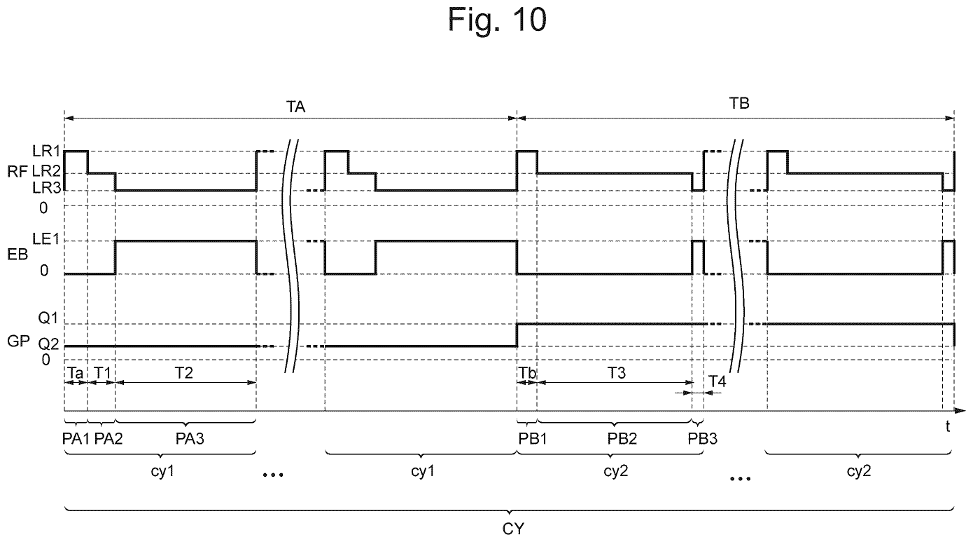

FIG. 10 is a diagram illustrating another example of supply of the source RF signal, the bias signal, and the processing gas in the cycle CY. The vertical axis and the horizontal axis in FIG. 10 are the same as those in FIG. 6. The power levels of the source RF signal and the bias signal illustrated in FIG. 10 are the same as those in FIG. 6, and the flow rate of the processing gas is different from that in FIG. 6. In this example, the flow rate (Q2) of the second processing gas supplied in the second cycle cy2 is smaller than the flow rate (Q1) of the first processing gas supplied in the first cycle cy1. As a result, the balance between the formation of the deposit and the etching can be different between the first cycle cy1 and the second cycle cy2.

In an embodiment, the flow rate of the first processing gas supplied in the first period T1 (step ST22) is different from the flow rate of the second processing gas supplied in the third period T3 (step ST26). In this case, T2/T1 and T4/T3 may be the same as or different from each other. As a result, the balance between the formation of the deposit and the etching can be different between the first cycle cy1 and the second cycle cy2. In an embodiment, the flow rate of the first processing gas supplied in the second period T2 (step ST23) is different from the flow rate of the second processing gas supplied in the fourth period T4 (step ST27). In this case, T2/T1 and T4/T3 may be the same as or different from each other. As a result, the balance between the formation of the deposit and the etching can be different between the first cycle cy1 and the second cycle cy2.

In an embodiment, the flow rate of the first processing gas supplied in the first period T1 (step ST22) is different from the flow rate of the first processing gas supplied in the second period T2 (step ST23). In this case, T2/T1 and T4/T3 may be the same as or different from each other. In an embodiment, the flow rate of the second processing gas supplied in the third period T3 (step ST26) is different from the flow rate of the second processing gas supplied in the fourth period T4 (step ST27). In this case, T2/T1 and T4/T3 may be the same as or different from each other.

In an embodiment, instead of executing step ST21 and step ST25 in step ST2, processing of igniting the plasma at the beginning of step ST22 and step ST26 may be executed. That is, the first ignition period and the second ignition period may be included in the first period T1 and the third period T3, respectively.

In an embodiment, in at least any one of step ST22, step ST23, step ST26, and step ST27 in step ST2, the second DC signal may be supplied from the second DC generator 32b to the upper electrode with the negative voltage. In an embodiment, by supplying the second DC signal to the upper electrode, any one or a plurality of the following effects (I) to (V) may be obtained. (I) A self-bias voltage of the upper electrode is increased to increase a sputtering effect on the surface of the upper electrode. (II) The plasma sheath in the upper electrode is enlarged to reduce the plasma. (III) The substrate W is irradiated with electrons generated in the upper electrode. (IV) The plasma potential is controlled. (V) The electron density of the plasma is increased.

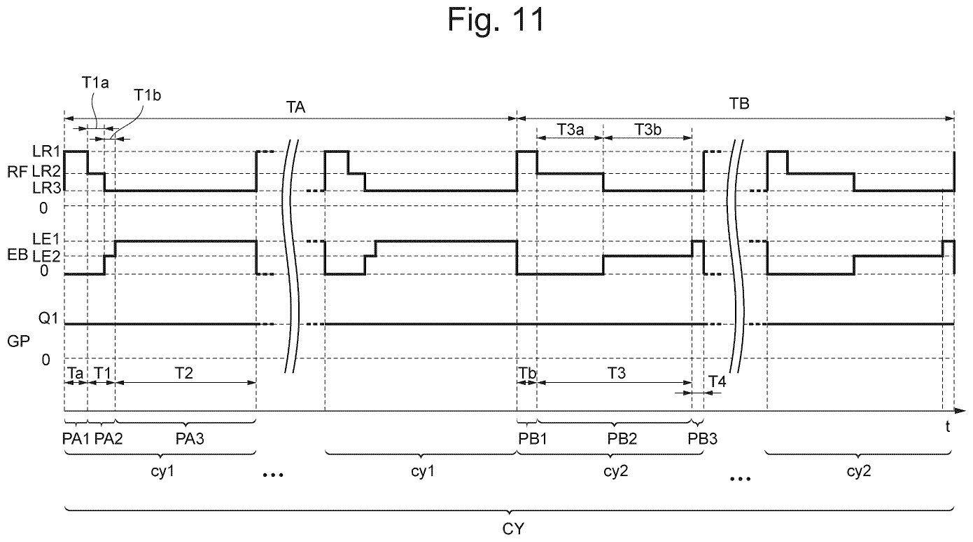

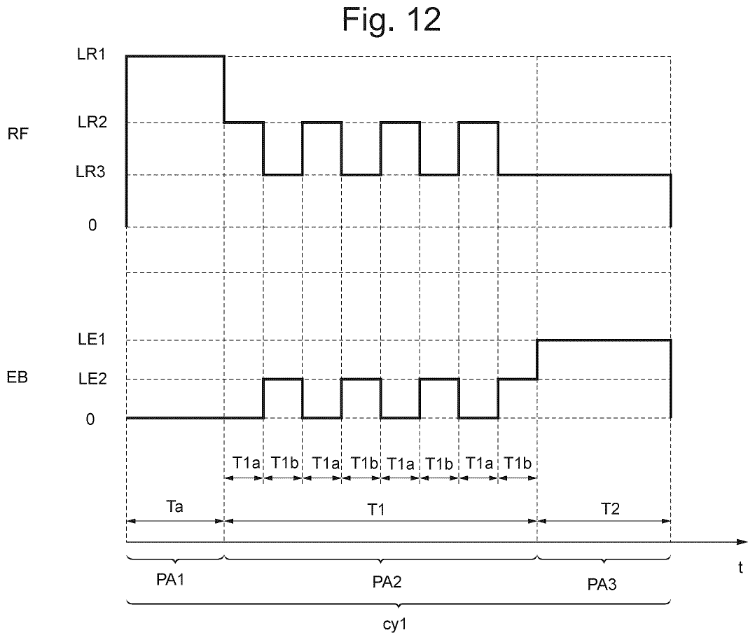

In an embodiment, the power levels of the source RF signal and the bias signal may be changed in the first period T1 (step ST22) and/or the third period (step ST26) of the cycle cy1, respectively. For example, the power levels of the source RF signal and the bias signal may be changed as illustrated in FIGS. 11 and 12.

FIG. 11 is a diagram illustrating another example of supply of the source RF signal, the bias signal, and the processing gas in the cycle CY. The vertical axis and the horizontal axis of FIG. 11 are the same as those of FIG. 6. In the example illustrated in FIG. 11, the first period T1 (step ST22) of the first cycle cy1 is configured of two periods T1a and T1b. In addition, the period T3 (step ST26) of the second cycle cy2 is configured of two periods T3a and T3b.

In the period T1a, the power level of the source RF signal is LR2, and the power level of the bias signal is zero. In the period T1b, the power level of the source RF signal is LR3 (<LR2), and the power level of the bias signal is LE2. Here, LE2 is a value larger than zero and smaller than LE3. That is, when the period T1a and the period T1b are compared with each other, the period T1a is a period in which the power level of the source RF signal is high and the power level of the bias signal is low. In addition, the period T1b is a period in which the power level of the source RF signal is low and the power level of the bias signal is high. As a result, the energy of the ions supplied to the deposit DP1 in the period T1b is higher than the energy of the ions supplied to the deposit DP1 in the period T1a. In the period T1b, the ions having relatively high energy are supplied to the deposit DP1, and unnecessary elements (for example, fluorine) are extracted from the deposit DP1. Therefore, in the deposit DP1 obtained in the period T1b, many bonds having high binding energy (for example, carbon-carbon bonds) may be formed.

The power levels of the source RF signals in the period T3a and the period T3b are the same as those in the period T1a and the period T1b, respectively. That is, the energy of the ions supplied to the deposit DP2 in the period T3b is higher than the energy of the ions supplied to the deposit DP2 in the period T3a. As a result, in the deposit DP2 obtained in the period T3b, many bonds having high binding energy (for example, carbon-carbon bonds) may be formed.

In the example illustrated in FIG. 11, as in the example illustrated in FIG. 6, the relationship of T2/T1>T4/T3 is established. That is, when the first cycle cy1 and the second cycle cy2 are compared with each other, the first cycle cy1 is a process in which etching is priority, and the second cycle cy2 is a process in which the formation of deposits is priority.

FIG. 12 is a diagram illustrating another example of supply of the source RF signal, the bias signal, and the processing gas in the cycle CY. The vertical axis and the horizontal axis of FIG. 12 are the same as those of FIG. 9A. In this example, the first period T1 (step ST22) of the first cycle cy1 is configured by repeating the cycle of the period T1a and the period T1b a plurality of times. The power levels of the source RF signal and the bias signal in the period T1a and the period T1b are the same as those described in FIG. 11. In this example as well, in the deposit DP1 obtained in the period T1b, many bonds having high binding energy (for example, carbon-carbon bonds) may be formed. In the same manner, in the third period T3 (step ST26) of the second cycle cy2, the third period T3 may be configured by repeating the cycle of the period T3a and the period T3b a plurality of times.

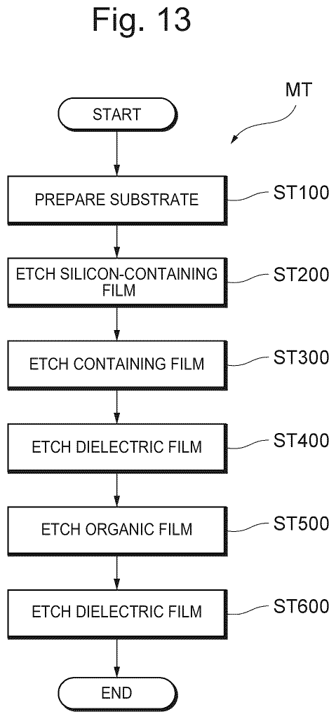

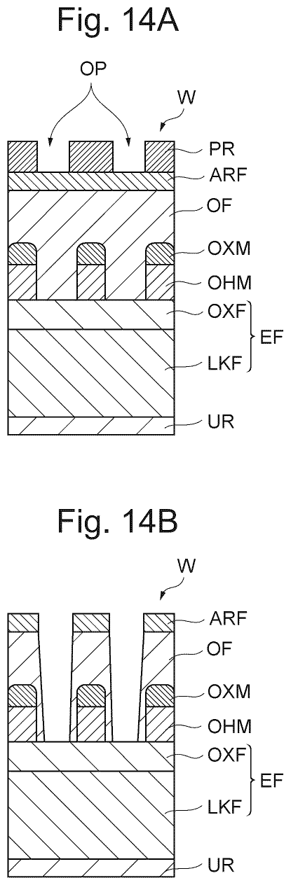

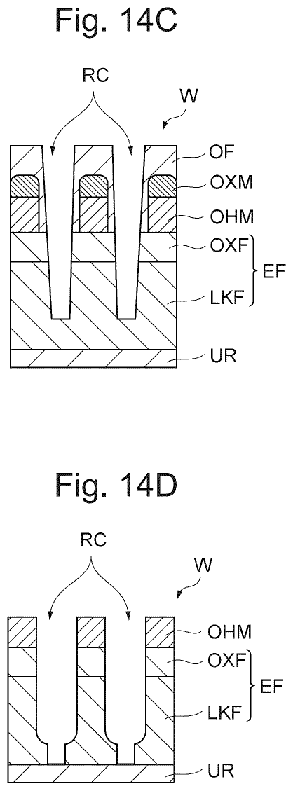

FIG. 13 is a flowchart illustrating an etching method (hereinafter, also referred to as a “method MT”) according to another exemplary embodiment. As illustrated in FIG. 13, the method MT includes step ST100 of preparing a substrate, step ST200 of etching a silicon-containing film, step ST300 of etching an organic film, step ST400 of etching a dielectric film, step ST500 of removing the organic film, and step ST600 of etching the dielectric film. In addition, FIGS. 14A to 14D are diagrams illustrating an example of a cross-sectional structure of the substrate W according to step ST100, step ST300, step ST400, and step ST600 of the method MT. The method MT may be executed by the plasma processing apparatus 1 illustrated in FIGS. 1 and 2. In the following, a case where the controller 2 controls each unit of the capacitively coupled plasma processing apparatus 1 (see FIG. 2) to execute the present processing method on the substrate W will be described with reference to FIGS. 13 and 14A to 14D.

### (Step ST100)

First, in step ST100, the substrate W is prepared in the plasma processing space 10s of the plasma processing apparatus 1. The substrate W is carried into the chamber 10 by a transport arm and is placed on the center region 111a of the substrate support 11. The substrate W is adsorbed and held on the substrate support 11 by the electrostatic chuck 1111.

FIG. 14A is a diagram illustrating an example of a cross-sectional structure of the substrate W prepared in step ST100. As illustrated in FIG. 14A, the substrate W includes an underlying film UR, a dielectric film EF, a metal-containing mask MHM, a silicon oxide film OXM, an organic film OF, a silicon-containing film ARF, and a resist mask PR. In an embodiment, the dielectric film EF may have a stacked structure including a low dielectric constant film LKF and a silicon oxide film OXF. The low dielectric constant film LKF may be, for example, a SiOCH film.

The metal-containing mask MHM is provided on the film EF. The metal-containing mask MHM has a pattern that is transferred to the dielectric film EF by etching. The metal-containing mask MHM provides one or more openings. In an embodiment, the metal-containing mask MHM contains at least one metal selected from the group consisting of tin, tungsten, molybdenum, and titanium. For example, the metal-containing mask MHM is formed of titanium nitride.

The silicon oxide film OXM is provided on a top portion of the metal-containing mask MHM. The organic film OF is provided such that the silicon oxide film OXM, the metal-containing film MHM, and the film EF are covered. The silicon-containing film ARF is provided on the organic film OF. In an embodiment, the silicon-containing film ARF is an antireflection film. The resist mask PR is provided on the silicon-containing film ARF. The resist mask PR is patterned using a photolithography technique. The resist mask PR provides one or more openings OP in order to form a concave portion (for example, a trench or a hole) in the film EF at a portion exposed from the metal-containing mask MHM.

### (Step ST200)

Next, in step ST200, the silicon-containing film ARF is etched. The processing gas is supplied into the plasma processing chamber 10. The processing gas includes, for example, a fluorocarbon gas and a noble gas (for example, Ar gas). In addition, the source RF signal is supplied to the lower electrode of the substrate support 11 and/or the upper electrode of the shower head 13. In this case, the bias signal may be supplied to the lower electrode. The plasma is formed from the processing gas, and a portion of the silicon-containing film ARF, which is not covered by the resist mask PR, is etched in a depth direction. As a result, the pattern of the resist mask PR is transferred to the silicon-containing film ARF.

### (Step ST300)

Next, in step ST300, the organic film OF is etched. The processing gas is supplied into the plasma processing chamber 10. The processing gas includes, for example, an oxygen-containing gas (for example, an oxygen gas). The processing gas may include a nitrogen gas and a hydrogen gas. In addition, the source RF signal is supplied to the lower electrode of the substrate support 11 and/or the upper electrode of the shower head 13. In this case, the bias signal may be supplied to the lower electrode. The plasma is formed from the processing gas, and a portion of the organic film OF that is not covered by the silicon-containing film ARF is etched in the depth direction. As a result, as illustrated in FIG. 14B, the pattern of the silicon-containing film ARF is transferred to the organic film OF.

### (Step ST400)

Next, in step ST400, the dielectric film EF is etched. In step ST400, step ST2 of the present processing method may be executed. That is, the above-described cycle CY may be repeated. As a result, as illustrated in FIG. 14C, the pattern of the organic film OF is transferred to the dielectric film EF, and the concave portion RC is formed in the dielectric film EF.

### (Step ST500)

Next, in step ST500, the organic film OF is removed. The processing gas is supplied into the plasma processing chamber 10. The processing gas includes, for example, an oxygen-containing gas (for example, an oxygen gas and/or a CO gas). In addition, the source RF signal is supplied to the lower electrode of the substrate support 11 and/or the upper electrode of the shower head 13. In this case, the bias signal may be supplied to the lower electrode. The plasma is formed from the processing gas, and the organic film OF is removed (ashed).

### (Step ST600)

Next, in step ST600, the dielectric film EF is further etched. In step ST600, step ST2 of the present processing method may be executed. That is, the above-described cycle CY may be repeated. As a result, as illustrated in FIG. 14D, the concave portion RC is further deeply etched.

### EXAMPLES

Next, examples of the present processing method will be described. The present disclosure is not limited by the following examples.

### Example 1

In Example 1, the present processing method was applied using the plasma processing apparatus 1, and a substrate having the same structure as the substrate W illustrated in FIG. 3 was etched. The mask MK of the substrate W was a metal-containing film consisting of titanium nitride, and the film EF was a silicon-containing insulating film.

In step ST2, the same cycle as the cycle CY illustrated in FIG. 6 was executed. The lengths of the first ignition period, the first period T1, and the second period T2 of the first cycle cy1 were 400 μs, 600 μs, and 4000 μs, respectively. In the source cycle CY supplied in the first ignition period Ta, the first period T1, and the second period T2, the first cycle cy1 was executed at a frequency of 0.2 kHz for 2 seconds. The first processing gas included a CF₄ gas, a C₄F₈ gas, an H₂ gas, an N₂ gas, and an Ar gas.

In step ST2, the lengths of the second ignition period, the third period T3, and the fourth period T4 of the second cycle cy2 were 400 μs, 4400 μs, and 200 μs, respectively. In the cycle CY, the second cycle cy2 was executed at a frequency of 0.2 kHz for 8 seconds. As the second processing gas, the same gas as the first processing gas was used. The etching in step ST2 was executed for 40 seconds.

### Example 2

In Example 2, the substrate W was etched under the same conditions as in Example 1 except for the following points. In Example 2, the first cycle cy1 in which the first ignition period, the first period T1, and the second period T2 each had the length of 400 μs, 400 μs, and 200 μs was executed at 1.0 KHz for 2 seconds. In addition, the second cycle cy2, which is the same as that of Example 1, was executed at 0.2 kHz for 5 seconds. The etching in step ST2 was executed for 49 seconds.

In Reference Example 1, the substrate W was etched by repeating a cycle CYa for 17 seconds. The cycle CYa included only the first cycle cy1 of Example 1 and did not include the second cycle cy2. The other conditions are the same as those in Example 1.

In Reference Example 2, the substrate W was etched by repeating a cycle CYb for 25 seconds. The cycle CYb included only the cycle cy1′ in which the lengths of the first ignition period, the first period T1, and the second period T2 of the first cycle cy1 of Example 1 were set to 400 μs, 2600 μs, and 2000 μs, respectively, and did not include the second cycle cy2. The other conditions are the same as those in Example 1.

In Reference Example 3, the substrate W was etched by repeating a cycle CYc for 120 seconds. The cycle CYc included only the second cycle cy2 of Example 1 and did not include the first cycle cy1.

In Reference Example 4, the substrate W was etched by repeating a cycle CYd for 20 seconds. The cycle Cyd included only the first cycle cy1 of Example 2 and did not include the second cycle cy2.

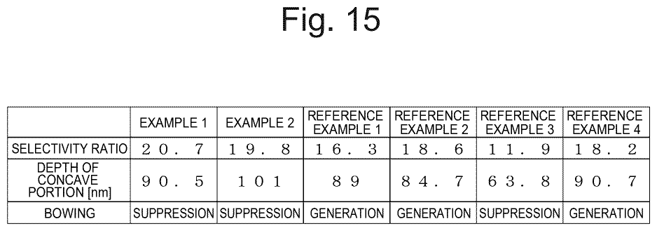

FIG. 15 illustrates results of the etching of Example 1, Example 2, and Reference Examples 1 to 4. In FIG. 15, “selectivity ratio” is the selectivity ratio of the film EF with respect to the mask MK. The “depth of the concave portion” indicates the depth of the concave portion RC of the film EF formed by etching, and the larger this value, the larger the removal property is. “Bowing” indicates the presence or absence of the bowing (the widening of the width of a part of the concave portion RC is increased thereby forming a barrel-shaped cross-sectional shape) in the concave portion RC.

As illustrated in FIG. 1, in the etching according to Examples 1 and 2, the selectivity ratio and the etching depth (removal property) were improved, and the bowing was also suppressed, as compared with Reference Examples 1 to 4. On the other hand, in Reference Examples 1 to 4, the improvement of the selectivity ratio, the securing of the removal property, and the suppression of the bowing are in a trade-off relationship, and all of them cannot be satisfied.

According to one exemplary embodiment of the present disclosure, it is possible to provide a technique for improving the controllability of etching.

The embodiments of the present disclosure further include the following aspects.

### Addendum 1

A plasma processing apparatus including:
a chamber;
a substrate support that is disposed in the chamber and includes a lower electrode;
a gas supply that is configured such that a bimodal gas is supplied into the chamber, the bimodal gas including an etching gas and a deposition gas;
a source RF generator that is configured such that a source RF signal is generated to form a plasma from the bimodal gas in the chamber, the source RF signal having a first source power level in a first deposition priority period and a second deposition priority period, and having a second source power level smaller than the first source power level in a first etching priority period and a second etching priority period, the first deposition priority period and the first etching priority period being included in each of a plurality of first sub-cycles in a first sequence, the second deposition priority period and the second etching priority period being included in each of a plurality of second sub-cycles in a second sequence, the first sequence and the second sequence being included in a main cycle, the first deposition priority period being shorter than the second deposition priority period, and the first etching priority period being longer than the second etching priority period; and
a bias RF generator that is electrically connected to the lower electrode and is configured such that a bias RF signal is generated, the bias RF signal having a first bias power level in the first deposition priority period and the second deposition priority period, and having a second bias power level larger than the first bias power level in the first etching priority period and the second etching priority period.

### Addendum 2

The plasma processing apparatus according to Addendum 1, in which the first bias power level is a zero voltage level.

### Addendum 3

A plasma processing apparatus including:
a chamber;
a substrate support that is disposed in the chamber and includes a lower electrode;
a gas supply that is configured such that a bimodal gas is supplied into the chamber, the bimodal gas including an etching gas and a deposition gas;
an RF generator that is configured such that an RF signal is generated to form a plasma from the bimodal gas in the chamber, the RF signal having a first power level in a first deposition priority period and a second deposition priority period, and having a second power level smaller than the first power level in a first etching priority period and a second etching priority period, the first deposition priority period and the first etching priority period being included in each of a plurality of first sub-cycles in a first sequence, the second deposition priority period and the second etching priority period being included in each of a plurality of second sub-cycles in a second sequence, the first sequence and the second sequence being included in a main cycle, the first deposition priority period being shorter than the second deposition priority period, and the first etching priority period being longer than the second etching priority period; and
a voltage pulse generator that is electrically connected to the lower electrode and is configured such that a voltage pulse signal is generated, the voltage pulse signal having a burst of voltage pulses having a first voltage level in the first deposition priority period and the second deposition priority period, and having a second voltage level in the first etching priority period and the second etching priority period, and an absolute value of the second voltage level being larger than an absolute value of the first voltage level.

### Addendum 4

The plasma processing apparatus according to Addendum 3, in which the second voltage level has a negative polarity.

### Addendum 5

The plasma processing apparatus according to Addendum 3 or 4, in which the first voltage level is a zero voltage level.

### Addendum 6

A power supply system including:
a first RF generator that is configured to generate a first RF signal, the first RF signal having a first power level in a first period and a second period, and having a second power level smaller than the first power level in a third period and a fourth period, the first period and the third period being included in each of a plurality of first sub-cycles in a first sequence, the second period and the fourth period being included in each of a plurality of second sub-cycles in a second sequence, the first sequence and the second sequence being included in a main cycle, the first period being shorter than the second period, and the third period being longer than the fourth period; and
a second RF generator that is configured such that a second RF signal is generated, the second RF signal having a third power level in the first period and the second period, and having a fourth power level larger than the third power level in the third period and the fourth period.

### Addendum 7

A power supply system including:
an RF generator that is configured such that an RF signal is generated, the RF signal having a first power level in a first period and a second period, and having a second power level smaller than the first power level in a third period and a fourth period, the first period and the third period being included in each of a plurality of first sub-cycles in a first sequence, and the second period and the fourth period being included in each of a plurality of second sub-cycles in a second sequence, the first sequence and the second sequence being included in a main cycle, the first period being shorter than the second period, and the third period being longer than the fourth period; and
a voltage pulse generator that is configured such that a voltage pulse signal is generated, the voltage pulse signal having a burst of voltage pulses having a first voltage level in the first period and the second period, and having a second voltage level in the third period and the fourth period, and an absolute value of the second voltage level being larger than an absolute value of the first voltage level.

### Addendum 9

An etching method including:
(a) preparing a substrate in a chamber of a plasma processing apparatus, the substrate including a film and a mask on the film; and
(b) etching the film including a cycle of supplying a pulse of a source RF signal and a pulse of a bias signal, the cycle including a first period, a second period, a third period, and a fourth period,
in the first period, a first deposit being formed on the substrate by a first plasma formed from a first processing gas,
in the second period, at least the pulse of the bias signal being supplied to the chamber, and the film being etched by the first plasma,
in the third period, a second deposit being formed on the substrate by a second plasma formed from a second processing gas, and
in the fourth period, at least the pulse of the bias signal being supplied to the chamber, and the film being etched by the second plasma,
in which a ratio of a length of the first period to a length of the second period is different from a ratio of a length of the third period to a length of the fourth period.

### Addendum 10

The etching method according to Addendum 9, in which the cycle includes a first ignition period in which a plasma is formed from the first processing gas by supplying the first processing gas to the chamber and supplying the pulse of the source RF signal before the first period or at the beginning of the first period.

### Addendum 11

The etching method according to Addendum 10, in which the cycle includes a second ignition period in which a plasma is formed from the second processing gas by supplying the second processing gas to the chamber and supplying the pulse of the source RF signal before the third period or at the beginning of the third period.

### Addendum 12

The etching method according to Addendum 11, in which a power level of the source RF signal supplied to the chamber in the cycle is largest in the first ignition period or the second ignition period.

### Addendum 13

The etching method according to any one of Addenda 9 to 12, in which the pulse of the source RF signal is supplied to the chamber in the first period and the third period.

### Addendum 14

The etching method according to Addendum 13, in which a power level of the source RF signal in the first period is different from a power level of the source RF signal in the third period.

### Addendum 15

The etching method according to any one of Addenda 9 to 14, in which a power level of the bias signal in the second period is different from a power level of the bias signal in the fourth period.

### Addendum 16

The etching method according to any one of Addenda 9 to 15, in which a power level of the bias signal supplied to the chamber in the cycle is largest in the second period or the fourth period.

### Addendum 17

The etching method according to any one of Addenda 9 to 16, in which the first processing gas is different from the second processing gas.

### Addendum 18

The etching method according to any one of Addenda 9 to 16, in which the first processing gas is the same as the second processing gas.

### Addendum 19

The etching method according to any one of Addenda 9 to 18, in which a flow rate of the first processing gas is different from a flow rate of the second processing gas.

### Addendum 20

The etching method according to any one of Addenda 9 to 18, in which a flow rate of the first processing gas is the same as a flow rate of the second processing gas.

### Addendum 21

The etching method according to any one of Addenda 9 to 20, in which, in the cycle, after a first cycle including the first period and the second period is repeated once or more, a second cycle including the third period and the fourth period is repeated once or more.

### Addendum 22

The etching method according to Addendum 21, in which a length of a period in which the first cycle is repeated is different from a length of a period in which the second cycle is repeated.

### Addendum 23

The etching method according to Addendum 21, in which a length of a period in which the first cycle is repeated is the same as a length of a period in which the second cycle is repeated.

### Addendum 24

An etching method including:
(a) preparing a substrate in a chamber of a plasma processing apparatus, the substrate including a film and a mask on the film; and
(b) etching the film including a cycle of supplying a pulse of a source RF signal and a pulse of a bias signal, the cycle including a first period, a second period, a third period, and a fourth period,
in the first period, at least the pulse of the source RF signal being supplied to the chamber, and a first deposit being formed on the substrate by a first plasma formed from a first processing gas,
in the second period, at least the pulse of the bias signal being supplied to the chamber, and the film being etched by the first plasma,
in the third period, at least the pulse of the source RF signal being supplied to the chamber, and a second deposit being formed on the substrate by a second plasma formed from a second processing gas, and
in the fourth period, at least the pulse of the bias signal being supplied to the chamber, and the film being etched by the second plasma,
in which a power level of the source RF signal supplied in the first period is different from a power level of the source RF signal supplied in the third period, or a power level of the bias signal supplied in the second period is different from a power level of the bias signal supplied in the fourth period.

### Addendum 25

An etching method including:
(a) preparing a substrate in a chamber of a plasma processing apparatus, the substrate including a film and a mask on the film; and
(b) etching the film including a cycle of supplying a pulse of a source RF signal and a pulse of a bias signal, the cycle including a first period, a second period, a third period, and a fourth period,
in the first period, a first deposit being formed on the substrate by a first plasma formed from a first processing gas,
in the second period, at least the pulse of the bias signal being supplied to the chamber, and the film being etched by the first plasma formed from the first processing gas,
in the third period, a second deposit being formed on the substrate by a second plasma formed from a second processing gas, and
in the fourth period, at least the pulse of the bias signal being supplied to the chamber, and the film being etched by a plasma formed from the second processing gas,
in which the first processing gas supplied in the first period has a different flow rate from the second processing gas supplied in the third period, or the first processing gas supplied in the second period has a different flow rate from the second processing gas supplied in the fourth period.

### Addendum 26

A plasma processing apparatus including: a chamber; and a controller, in which the controller executes
(a) control of preparing a substrate in the chamber of the plasma processing apparatus, the substrate including a film and a mask on the film and
(b) control of etching of the film including a cycle of supplying a pulse of a source RF signal and a pulse of a bias signal, the cycle including a first period, a second period, a third period, and a fourth period,
in the first period, a first deposit being formed on the substrate by a first plasma formed from a first processing gas,
in the second period, at least the pulse of the bias signal being supplied to the chamber, and the film being etched by the first plasma,
in the third period, a second deposit being formed on the substrate by a second plasma formed from a second processing gas, and
in the fourth period, at least the pulse of the bias signal being supplied to the chamber, and the film being etched by the second plasma, and
a ratio of a length of the first period to a length of the second period is different from a ratio of a length of the third period to a length of the fourth period.

### Addendum 27

A plasma processing apparatus including: a chamber; and a controller, in which the controller executes
(a) control of preparing a substrate in the chamber of the plasma processing apparatus, the substrate including a film and a mask on the film and
(b) control of etching of the film including a cycle of supplying a pulse of a source RF signal and a pulse of a bias signal, the cycle including a first period, a second period, a third period, and a fourth period,
in the first period, at least the pulse of the source RF signal being supplied to the chamber, and a first deposit being formed on the substrate by a first plasma formed from a first processing gas,
in the second period, at least the pulse of the bias signal being supplied to the chamber, and the film being etched by the first plasma,
in the third period, at least the pulse of the source RF signal being supplied to the chamber, and a second deposit being formed on the substrate by a second plasma formed from a second processing gas, and
in the fourth period, at least the pulse of the bias signal being supplied to the chamber, and the film being etched by the second plasma, and
a power level of the source RF signal supplied in the first period is different from a power level of the source RF signal supplied in the third period, or a power level of the bias signal supplied in the second period is different from a power level of the bias signal supplied in the fourth period.

### Addendum 28

A plasma processing apparatus including: a chamber; and a controller, in which the controller executes
(a) control of preparing a substrate in the chamber of the plasma processing apparatus, the substrate including a film and a mask on the film and
(b) control of etching of the film including a cycle of supplying a pulse of a source RF signal and a pulse of a bias signal, the cycle including a first period, a second period, a third period, and a fourth period,
in the first period, a first deposit being formed on the substrate by a first plasma formed from a first processing gas,
in the second period, at least the pulse of the bias signal being supplied to the chamber, and the film being etched by the first plasma formed from the first processing gas,
in the third period, a second deposit being formed on the substrate by a second plasma formed from a second processing gas, and
in the fourth period, at least the pulse of the bias signal being supplied to the chamber, and the film being etched by a plasma formed from the second processing gas, and
the first processing gas supplied in the first period has a different flow rate from the second processing gas supplied in the third period, or the first processing gas supplied in the second period has a different flow rate from the second processing gas supplied in the fourth period.

Each of the above embodiments is described for the purpose of description, and it is not intended to limit the scope of the present disclosure. Each of the above embodiments may be modified in various ways without departing from the scope and gist of the present disclosure. For example, some configuration elements in one embodiment are able to be added to other embodiments. In addition, some configuration elements in one embodiment are able to be replaced with corresponding configuration elements in another embodiment.

What is claimed is:

1. A plasma processing apparatus comprising:
a chamber;
a substrate support disposed in the chamber and including a lower electrode;
a gas supply configured to supply a bimodal gas into the chamber, the bimodal gas including an etching gas and a deposition gas;
a source RF generator configured to generate a source RF signal to form a plasma from the bimodal gas in the chamber, wherein
the source RF signal includes:
a first source power level in a first deposition priority period and a second deposition priority period, and
a second source power level smaller than the first source power level in a first etching priority period and a second etching priority period,
the first deposition priority period and the first etching priority period are included in each of a plurality of first sub-cycles in a first sequence,
the second deposition priority period and the second etching priority period are included in each of a plurality of second sub-cycles in a second sequence,
the first sequence and the second sequence are included in a main cycle,
the first deposition priority period is shorter than the second deposition priority period, and
the first etching priority period is longer than the second etching priority period; and
a bias RF generator electrically connected to the lower electrode and configured to generate a bias RF signal, the bias RF signal including:
a first bias power level in the first deposition priority period and the second deposition priority period, and
a second bias power level larger than the first bias power level in the first etching priority period and the second etching priority period.

2. The plasma processing apparatus according to claim 1, wherein the first bias power level is a zero voltage level.

3. A plasma processing apparatus comprising:
a chamber;
a substrate support disposed in the chamber and including a lower electrode;
a gas supply configured to supply a bimodal gas into the chamber, the bimodal gas including an etching gas and a deposition gas;
an RF generator configured to generate an RF signal to form a plasma from the bimodal gas in the chamber, wherein
the RF signal includes:
a first power level in a first deposition priority period and a second deposition priority period, and
a second power level smaller than the first power level in a first etching priority period and a second etching priority period,
the first deposition priority period and the first etching priority period are included in each of a plurality of first sub-cycles in a first sequence,
the second deposition priority period and the second etching priority period are included in each of a plurality of second sub-cycles in a second sequence,
the first sequence and the second sequence are included in a main cycle,
the first deposition priority period is shorter than the second deposition priority period, and
the first etching priority period is longer than the second etching priority period; and
a voltage pulse generator electrically connected to the lower electrode and configured to generate a voltage pulse signal, the voltage pulse signal including a burst of voltage pulses having a first voltage level in the first deposition priority period and the second deposition priority period, and a second voltage level in the first etching priority period and the second etching priority period, and an absolute value of the second voltage level being larger than an absolute value of the first voltage level.

4. The plasma processing apparatus according to claim 3, wherein the second voltage level has a negative polarity.

5. The plasma processing apparatus according to claim 4, wherein the first voltage level is a zero voltage level.

6. An etching method comprising:
(a) preparing a substrate in a chamber of a plasma processing apparatus, the substrate including a film and a mask on the film; and
(b) etching the film including a cycle of supplying a pulse of a source RF signal and a pulse of a bias signal, the cycle including a first period, a second period, a third period, and a fourth period, wherein
in the first period, a first deposit is formed on the substrate by a first plasma formed from a first processing gas,
in the second period, at least the pulse of the bias signal is supplied to the chamber, and the film being etched by the first plasma,
in the third period, a second deposit is formed on the substrate by a second plasma formed from a second processing gas,
in the fourth period, at least the pulse of the bias signal being supplied to the chamber, and the film is etched by the second plasma, and
wherein a ratio of a length of the first period to a length of the second period is different from a ratio of a length of the third period to a length of the fourth period.

7. The etching method according to claim 6, wherein the cycle includes a first ignition period in which a plasma is formed from the first processing gas by supplying the first processing gas to the chamber and supplying the pulse of the source RF signal before the first period or at the beginning of the first period.

8. The etching method according to claim 7, wherein the cycle further includes a second ignition period in which a plasma is formed from the second processing gas by supplying the second processing gas to the chamber and supplying the pulse of the source RF signal before the third period or at the beginning of the third period.

9. The etching method according to claim 8, wherein a power level of the source RF signal supplied to the chamber in the cycle is largest in the first ignition period or the second ignition period.

10. The etching method according to claim 6, wherein the pulse of the source RF signal is supplied to the chamber in the first period and the third period.

11. The etching method according to claim 10, wherein a power level of the source RF signal in the first period is different from a power level of the source RF signal in the third period.

12. The etching method according to claim 6, wherein a power level of the bias signal in the second period is different from a power level of the bias signal in the fourth period.

13. The etching method according to claim 6, wherein a power level of the bias signal supplied to the chamber in the cycle is largest in the second period or the fourth period.

14. The etching method according to claim 6, wherein the first processing gas is different from the second processing gas.

15. The etching method according to claim 6, wherein the first processing gas is the same as the second processing gas.

16. The etching method according to claim 6, wherein a flow rate of the first processing gas is different from a flow rate of the second processing gas.

17. The etching method according to claim 6, wherein a flow rate of the first processing gas is the same as a flow rate of the second processing gas.

18. The etching method according to claim 6, wherein, in the cycle, after a first cycle including the first period and the second period is repeated once or more, a second cycle including the third period and the fourth period is repeated once or more.

19. The etching method according to claim 18, wherein a length of a period in which the first cycle is repeated is different from a length of a period in which the second cycle is repeated.

20. The etching method according to claim 18, wherein a length of a period in which the first cycle is repeated is the same as a length of a period in which the second cycle is repeated.
